(19) United States
(12) Patent Application Publication
(10) Pub. No.: US 2012/0315405 A1
(43) Pub. Date: Dec. 13, 2012

(54) HOT WIRE CHEMICAL VAPOR DEPOSTION (HWCVD) WITH CARBIDE FILAMENTS

(75) Inventors: Marc Landry, Golden, CO (US); Ina Martin, Garfield Heights, OH (US); Maxim Shub, Golden, CO (US); Charles Teplin, Golden, CO (US); John Mariner, Avon Lake, OH (US); James Portugal, Irvine, CA (US)

(73) Assignee: ALLIANCE FOR SUSTAINABLE ENERGY, LLC, Golden, CO (US)

(21) Appl. No.: 13/580,595

(22) PCT Filed: Feb. 25, 2011
(86) PCT No.: PCT/US11/26210

§ 371 Date: Aug. 22, 2012

Related U.S. Application Data
(60) Provisional application No. 61/308,504, filed on Feb. 26, 2010.

(51) Int. Cl. C23C 16/32

(52) U.S. Cl. 427/587; 118/723 R

(57) ABSTRACT

A hot wire chemical vapor deposition apparatus for use in depositing thin films such as amorphous or epitaxial silicon upon a surface of a wafer or substrate by cracking a source or precursor gas such as silane. The apparatus includes a vacuum chamber and a source of precursor gas operable to inject the precursor gas into the chamber. The HWCVD apparatus also includes a heater with a support surface exposed to the deposition chamber, and the heater is operable to heat a substrate positioned upon the support surface. The apparatus includes a catalytic decomposition assembly with a filament positioned between the heater and the precursor gas inlet for selectively passing a current through the filament to resistively heat material of the filament. The filament material may be carbide such as tantalum carbide, which may be coated on a graphite core.

### CROSS-REFERENCE TO RELATED APPLICATIONS

This application claims the benefit of U.S. Provisional Application No. 61/308,504 filed Feb. 26, 2010, which is incorporated herein by reference in its entirety.

### CONTRACTUAL ORIGIN

The United States Government has rights in this invention under Contract No. DE-AC36-08GO28308 between the United States Department of Energy and the Alliance for Sustainable Energy, LLC, the Manager and Operator of the National Renewable Energy Laboratory.

### BACKGROUND

Thin films of semiconductor and other materials are widely used in many products such as integrated circuits (ICs), display devices, solar cells, and the like. The thin films are often provided by applying a layer or volume of material on to a substrate using chemical vapor deposition (CVD). In a typical CVD process, a wafer or substrate is exposed to one or more volatile precursors, which react and/or decompose on the substrate surface to provide the desired deposit or thin film.

Recently, there has been a growing interest in using hot wire CVD (HWCVD) processes because it has many advantages over other CVD processes, and these advantages include high growth rates, flexible process conditions, and intrinsic scalability. Briefly, HWCVD uses a hot or high temperature filament to chemically decompose or “crack” a source gas to cause the wafer or substrate to be coated with a thin film (e.g., coat a substrate with silicon from silane source gas).

In one specific example, HWCVD has been performed that involves the catalytic decomposition of silane (e.g., a source gas of SiH₄) with a resistively heated filament and has produced photovoltaic devices or solar cells, thin film transistors, and other devices with silicon thin films with state-of-the-art properties. In these HWCVD implementations, the source or feedstock gases of silane or silane/hydrogen mixtures are efficiently cracked into atomic radicals at the surface of the hot filament formed typically of tungsten or tantalum when the filament is kept at temperatures significantly higher than 1500° C. such as up to about 1800 to 2100° C. The reactive species are transported to the wafer or substrate surface in a low pressure ambient that enables a high deposition rate. For example, high quality amorphous silicon films have been deposited using tantalum filaments to crack silane source gas at acceptably high deposition rates.

There are several problems and issues that have inhibited rapid commercialization of HWCVD in the manufacture of thin film devices such as solar cells. The filaments are typically very small diameter wire filaments (e.g., about 1 millimeter or less), which may limit their structural strength for repeated deposition processes. Further, the filaments are often structurally instable in the reactive environments used in film growth, and this instability often leads to failure of the filaments after or during each deposition cycle. As a result, a standard practice is to replace all filaments after each thin film deposition.

For example, HWCVD of silicon thin films may be performed with tungsten (W) or tantalum filaments used to crack the source gas of silane. The filaments are resistively heated to high temperatures (e.g., tungsten and tantalum filaments conduct electricity but the resistive qualities of the filament result in heat generation) to provide the catalytic conversion of the source gas. To this end, a direct or alternating current is typically passed through the filament by connecting the ends of the filaments to positive and negative electrodes. As a result, the ends of the filaments near the cooler contacts are believed to be at lower temperatures than the central portions of the filament, and tungsten silicide or tantalum silicide forms at the ends of the filaments such that the filament has a larger diameter at its ends where this silicide forms. Unfortunately, both of these silicides are brittle, and the filaments break due to the silicidation after one or a limited number of deposition cycles. Since tantalum and tungsten filaments are not durable, their use with source gases such as silane are likely limited to research and testing facilities and will not be used for commercialized CVD processes.

Additionally, presently utilized filament materials may limit the deposition rates that can be achieved. Specifically, some materials limit the amount of heating that can be provided to crack the source gas. For example, tantalum filaments may start to soften and bow when they are heated above about 1800° C., and this limits the thermal energy available to decompose the precursor gas, which limits the deposition rate. Similarly, tungsten filaments are limited to temperatures of about 2100° C. before it begins to bow or structurally degrade. The filament bowing above certain temperatures, which may be useful for CVD processes, leads to control issues with the deposition rate and also with chemistry (e.g., of the source gas, with additive gases, and the like).

The foregoing examples of the related art and limitations related therewith are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods that are meant to be exemplary and illustrative, not limiting in scope. In various embodiments, one or more of the above-described problems have been reduced or eliminated, while other embodiments are directed to other improvements.

It was recognized that hot wire chemical vapor deposition (HWCVD) will be widely adopted in a commercial setting for use in providing thin films (e.g., a silicon layer on a photovoltaic device (PV) device) when filament materials can be provided that are stable and durable in the reactive and high temperature environments used in film growth. It was also understood that the filaments used to replace existing filaments such as a tungsten filament need to be a resistance heater and be structurally sound. In other words, the material used in the filament assembly needs to be properly conductive of electricity to be heated due to its resistive characteristics (e.g., to temperatures in the range of 1500 to 2100° C. or higher). Also, the filament preferably would have the structural strength and elasticity (non-brittleness) to be shaped as desired and not break or fail during repeated use even when provided in smaller dimensions (e.g., a diameter of 1 millimeter or less). For example, it may be desirable to provide the filament in the shape of a ribbon or a coil or be provided with a stress-relieving section (e.g., a spring-shaped portion to account for expansion and contraction during resistive heating and cooling cycles).

To this end, a thin film deposition apparatus is provided that facilitates effective HWCVD. The deposition apparatus includes a deposition chamber kept at lower or vacuum pressures and a heater within or exposed to the chamber that is used to support and heat a wafer or substrate, upon which a thin film is to be deposited. The deposition apparatus also includes an inlet from a source of precursor or feedstock gas (or simply “source gas”) such as silane or the like. The apparatus may also include inlets from other gas sources such as dopants or other additives such as hydrogen or the like.

In the chamber, one or more resistive-heater filaments are positioned in locations where the gas(es) will flow over the filaments and be rapidly heated and, in some cases, cracked into smaller components or molecules, which results in a coating of the heated wafer or substrate surfaces. The filament is attached to electrical contacts or fixtures extending to a power source (e.g., a source of DC or AC current) to selectively heat the filament to high or the desired temperatures. Significantly, the filament is formed at least partially of carbide such as tantalum carbide with some embodiments utilizing a graphite structure (such as a rod, a ribbon, a coil, a woven cloth, or the like) that is coated with a carbide to allow it to resist the reactive environment while other embodiments may utilize wholly (or nearly wholly) carbide materials for the filaments. For example, a carbon-source structure such as a graphite sheet or cloth may be processed to form a carbide such as tantalum carbide and the “threads” of graphite are consumed in the process leaving little or no core of graphite), and this carbide sheet/cloth may then be used as the HWCVD filament in the disclosed thin film deposition apparatus.

Exemplary embodiments described herein use a filament material including tantalum carbide (TaC) coated over a graphite core. For example, a filament in the shape of a rod may have a core of graphite with a thin layer of TaC. The TaC-coated graphite filament design has been proven by testing to be stable during silicon deposition from silane gas over a wide temperature range. The TaC-coated graphite filament may be used for the efficient catalytic decomposition of silane (e.g., the source or precursor gas in the deposition apparatus) to grow both amorphous and epitaxial thin films via HWCVD. The TaC-coated graphite filament material addresses at least the silicidation and stability issues associated with pure tantalum or tungsten filaments that led to shortened filament life spans and significantly increased material and maintenance costs of HWCVD with such filaments. It is believed that the functional advantages provided by TaC-coated graphite filaments and other carbide filaments described herein may be successfully implemented in large scale commercial HWCVD applications. This is likely the case as the carbide filaments also enable stable operations of the filament over a wide range of temperatures (e.g., higher temperatures than for tungsten or tantalum filaments), which may result in improved processing flexibility without downtimes associated with changing filaments to utilize differing filament materials.

In one particular example, a hot wire chemical vapor deposition (HWCVD) apparatus is provided for use in depositing thin films such as amorphous or epitaxial silicon upon a surface of a wafer or substrate by cracking a source or precursor gas such as silane. The apparatus includes a deposition chamber operable at vacuum and a source of precursor gas, which has a gas inlet selectively operable to inject or provide a volume of the precursor gas into the deposition chamber. The HWCVD apparatus also includes a heater with a support surface exposed to the deposition chamber, and the heater is operable to heat a substrate positioned upon the support surface (e.g., to an initial deposition temperature of 500° C. or more). Further, the apparatus includes a catalytic decomposition assembly that includes a filament positioned between the support surface of the heater and the precursor gas inlet, and the decomposition assembly also includes a power source for selectively passing a current through the filament to resistively heat material of the filament.

To increase durability, the filament material includes a carbide that is less reactive with the source or precursor gas. For example, the carbide may be tantalum carbide (TaC). The TaC may be provided as an outer layer that coats a carbon source core, which may be a graphite core (e.g., the TaC layer may be formed from a base graphite structure such as a graphite wire/rod, a graphite cloth, a graphite spring, a graphite coil, a graphite ribbon, or nearly any other shape or orientation). In some embodiments, the filament is heated to a temperature of at least about 2000° C. during operation of the power source (e.g., to 2100° C. or higher, which is greater than prior filaments could withstand without degradation). In some cases, the precursor gas is silane, SiCl₄, SiF₄, HSiCl₃, methane, or GeH₄, and the carbide is a coating provided over a graphite core. In these and other implementations, the carbide coating may be an alloy of carbon and a metallic or semi-metallic element, e.g., the carbide may be an alloy of carbon and at least one of tantalum, tungsten, molybdenum, niobium, scandium, yttrium, zirconium, silicon, and vanadium.

In addition to the exemplary aspects and embodiments described above, further aspects and embodiments will become apparent by reference to the drawings and by study of the following descriptions.

### BRIEF DESCRIPTION OF THE DETAILED DRAWINGS

Exemplary embodiments are illustrated in referenced figures of the drawings. It is intended that the embodiments and figures disclosed herein are to be considered illustrative rather than limiting.

FIG. 1 illustrates in simplistic form a portion of a HWCVD apparatus (or a thin film deposition system) of an embodiment showing use of a rod-shaped carbide filament (with the understanding that a typical HWCVD will include a plurality of such filaments);

FIG. 2 illustrates a functional block diagram showing schematically a deposition system useful for applying a thin film of silicon or other materials upon a wafer or substrate surface;

FIGS. 3A and 3B are cross sectional views of two embodiments of filaments that may be used as the filament of the HWCVD apparatus of FIG. 1 showing a carbide coated filament and a wholly carbide filament (or one in which the core or carbon source is substantially converted into carbide);

FIG. 4 is a graph plotting deposition rates achieved during testing with a carbide-coated filament (tantalum carbide coating a graphite core) and with a conventional tungsten filament; and

FIG. 5 illustrates a filament element (or catalytic deposition element) useful in a deposition system, such as that of FIGS. 1 and 2, showing use of a woven cloth formed of carbide-coated “threads” or carbide material in the body or sheet of the element and pores for allowing the source gas (or cracked gaseous components) to flow onto a substrate or wafer surface.

### DESCRIPTION

The following description is directed generally to thin film deposition assemblies or systems, and deposition methods, that make use of a resistive-heater filament to crack or provide catalytic decomposition of a source or precursor gas to cause a thin film of material to be deposited on a wafer, substrate, or other surface within a vacuum/deposition chamber. Generally, the filaments may be thought of as carbide filaments (of nearly any shape) such as a carbide-coated filament or one that may be all or nearly all carbide material.

Briefly, embodiments of a thin film deposition system are disclosed that use one or more tantalum carbide (TaC)-coated graphite filaments (e.g., a graphite wire coated with an outer layer or crust of TaC). The filaments are described as being used, for example, for cracking gaseous feedstock for deposition of thin films, coatings, or synthesis of materials employing hot wire chemical vapor deposition (HWCVD). Exemplary embodiments of filament may include a graphite material or core (e.g., a rod or wire, a ribbon, a thread/material of cloth, or the like) with a thin carbide coating.

The carbide may be an alloy of carbon (e.g., the graphite core may be a carbon source during manufacture or production of the filament). The material alloyed with the carbon may be varied to provide the carbide material of the filament, and, in some cases, the material is one or more metallic or semi-metallic elements such as, but not limited to, tantalum, tungsten, molybdenum, niobium, scandium, yttrium, zirconium, silicon, and vanadium. Applicability and usefulness in achieving a desired thin film, high deposition rate, structural integrity, and durability has been demonstrated, with good or encouraging results, through testing, and some of these test results are presented in the following description.

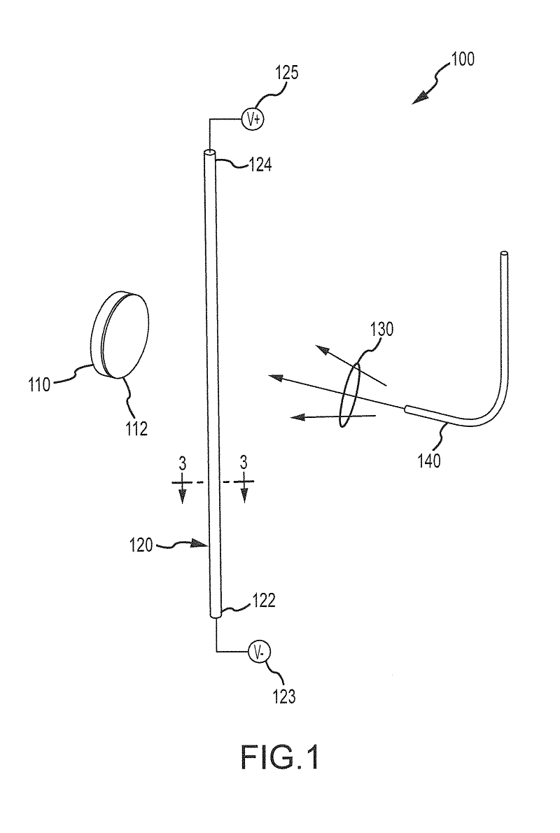

FIG. 1 is a schematic view of a portion of an exemplary HWCVD apparatus (or thin film deposition apparatus) 100 configured to make use of the improved filaments of the present description. The HWCVD apparatus 100 includes a heater 110 upon which a waver or substrate 112 is mounted. The heater 110 may be used, for example, to heat the wafer 112 to a temperature useful for initiating or facilitating deposition of a layer of material such as silicon, and, to this end, the heater 110 may heat the wafer 112 to temperature up to about 550° C. or the like with temperatures of 350 to 520° C. being common for maximum temperatures provided by heater 110.

The HWCVD apparatus 100 further includes a gas inlet 140 that is in fluid communication with a source of feedstock or precursor gas (not shown in FIG. 1) such as a source of silane or the like. During operation of the HWCVD apparatus 100, a volume of the precursor gas 120 is caused to flow at a predefined rate into the HWCVD apparatus. In this regard, the heater 110 is arranged such that the wafer/substrate 112 is exposed to or faces the gas inlet 140.

A carbide filament 120 is provided in the HWCVD apparatus 100 and positioned between the gas inlet 140 and the wafer/substrate 112. The HWCVD apparatus 100 also includes electrical contacts or connections 123, 125 that are affixed or attached to the filament 130 at its opposite ends 122, 124, respectively. During operation of the HWCVD apparatus 100 a voltage is applied to the ends 122, 124 of the filament so as to resistively heat the filament 120 along its length. In this way, for example, the surfaces of the filament 120 exposed to the flowing gas 130 are heated via a DC current to temperatures between 1500° C. and 2100° C. (or higher), while other temperatures may be useful depending upon the precursor gas and other deposition parameters. Gas flow is shown by arrows 130 flowing out of inlet 140 past the hot surfaces of filament 120, where the gas is cracked into reactive radicals causing a layer of material to be deposited upon exposed surfaces of substrate/wafer 112.

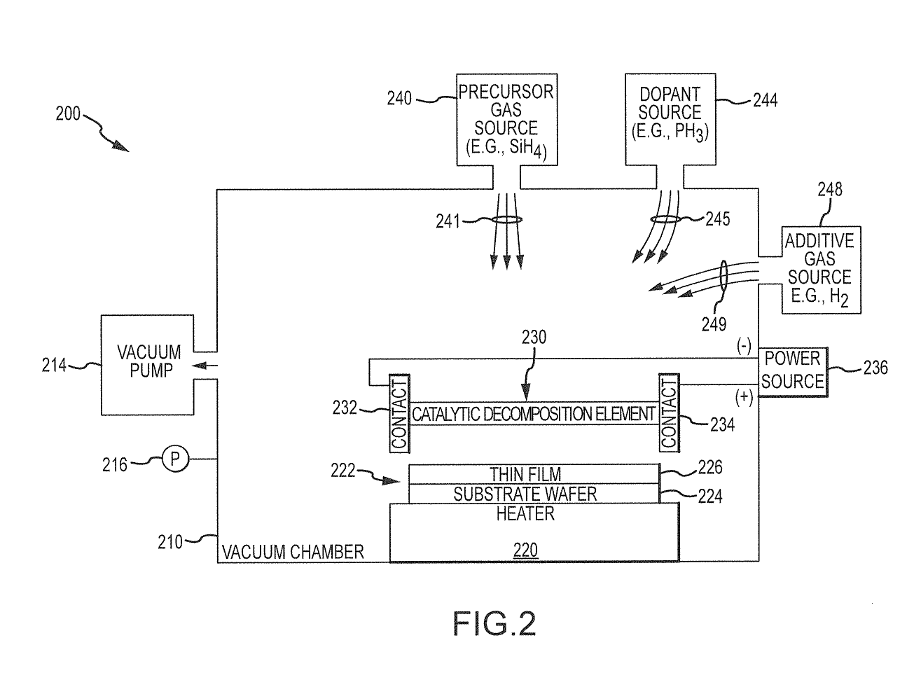

FIG. 2 illustrates a thin film deposition assembly 200 in functional block form, which may be useful for more fully understanding how the filaments described herein may be used in a HWCVD or similar deposition process. The assembly 200 includes a deposition or vacuum chamber 210 that may have an interior volume connected to a vacuum pump, e.g., a high or ultrahigh vacuum pump well-known in the industry, to maintain the chamber 210 at low pressures as measured with pressure gauge 216 (e.g., 50 to 90 percent vacuum or higher vacuum depending on the deposition process). A heater 220 is provided in the chamber 210 (or extending into the chamber 210), and a substrate or wafer 224 is shown to be supported upon or mounted to the heater 220. During operation of the assembly 200, the heater 220 may be used to raise the temperature of the substrate 224 to a temperature that facilitates the deposition of a particular layer of material such as an amorphous silicon film 226 for which the heater 220 may heat the wafer 224 to a temperature of 400 to 500° C. or the like while other embodiments call for much higher temperatures such as up to about 900° C. or higher (e.g., for crystalline silicon 226) and others call for the heater 220 to be turned off such that the wafer 224 is at much lower temperatures during film deposition.

As shown, the assembly 200 includes a catalytic decomposition element 230 that is supported above the heater 220 by electrical contacts or fixtures 232, 234 such that the decomposition element 230 is electrically linked to a power source 236. The decomposition element 230 may take the form of one, two, three or more carbide filaments having one or more form factors (e.g., a rod, a ribbon, a spring, or the like) or another useful form such as a cloth or sheet of interwoven carbon threads or wires with pores for allowing gas to pass through to the heater 220 and a supported wafer 224. During operation of the assembly 200, the catalytic decomposition element 230 is mounted in the mounting assembly including fixtures 232, 234, and the assembly including the element 230 is positioned within the chamber 210 and current is passed through the element 230 by operation of power source 236 to resistively heat the element 230 to temperatures that are high enough to crack the feedstock or precursor gas 241.

As shown, a film 226 is grown on the substrate or wafer 224 to form a thin film device (e.g., a solar cell, a display, a transistor, or the like). To this end, the assembly 200 includes a precursor gas source 240 (e.g., a source of silane or the like) that is operable via a mechanism (control valves and metering devices) (not shown) to precisely meter the amount and flow rate of feedstock gas 241 injected into the chamber 210. The filament assembly or decomposition element 230, which is now within a desired high temperature range, cracks the feedstock gas 241, and the hot, decomposed gas proceeds to grow a thin film 226 on the substrate or wafer 224 to provide the thin film device 222.

The assembly 200 may further include an optional dopant source 244 to inject dopants such as PH₃ into the chamber 210 so as to enhance deposition of thin film 226 and/or to alter the chemical makeup of the film 226. Similarly, additive gases 249, such as hydrogen or the like, may be provided in the chamber 210 during deposition of film 226 via gas source 248, which may be desirable to better affect deposition of the thin film 226.

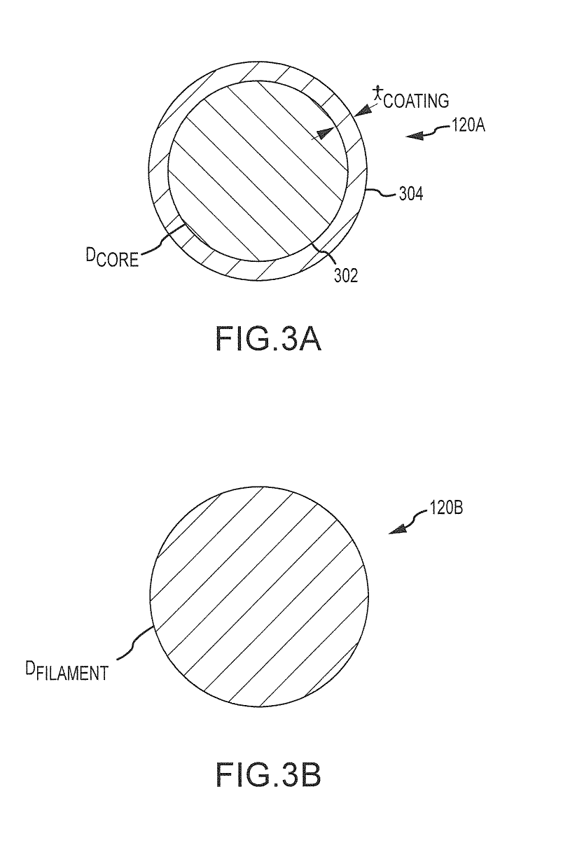

FIGS. 3A and 3B are cross-sectional views of the carbide filament 120 of FIG. 1. FIG. 3A shows an embodiment of filament 120A in which a carbide filament is provided in the form of a core 302 that is coated with a carbide coating or layer of carbide material 304. For example, the core 302 may be a core of material that is a carbon source for forming the carbide layer or coating 304. In one embodiment, the carbide 304 is an alloy of carbon that is formed from a graphite core 302 such that the core 302 has a diameter, D_{Core}, that is relatively large while a thin layer 304 of carbide is formed over the core 302 with a thickness, t_{Coating} (e.g., a layer of 20 to 40 microns or the like over a core 302). In some cases, the process of forming the carbide coating 304 is self limiting because the layer/coating 304 blocks a reactive gas from accessing the core 302, which ends the build up of carbide or the alloying process. This is typically the case where a graphite rod or wire is processed with a reactive gas to form a layer/coating of tantalum carbide (TaC) 304 over a graphite core 302.

FIG. 3B illustrates an embodiment of a filament 120B in which a wholly (or nearly so as a small graphite or carbon core may remain) carbide filament is provided with a particular diameter, D_{Filament}. For example, the self-limiting process discussed above may be overcome in some cases by using a base or original rod having a relatively small diameter or dimensions such that the reactive gas is always able to access additional carbon. It is believed that the filament 120B may be formed using, for example, a graphite (or other carbon source) rod or wire with a diameter, D_{Filament}, of less than about 40 microns or, more preferably, less than about 20 microns such that the filament 120B is fully formed into the carbon alloy or carbide (e.g., TaC). This may be the case when a graphite cloth is processed to form TaC when the threads or wires of such cloth have dimensions less than about 20 to 40 microns.

With regard to FIG. 3A, the thickness, t_{Coating}, of the carbide material 304 may vary to practice the thin film deposition assemblies. This layer 304 acts to provide a less reactive surface or protective coating for the resistive heating filament to resist formation of silicides or other materials that may cause failure of the filament (e.g., cause the ends of the filament to become brittle or otherwise impair its functionality). To this end, the thickness may be 20 to 40 microns or some thinner layer (e.g., 10 to 20 microns or less) while still providing adequate reaction resistance. The cross-sectional shape may be circular as shown but many other cross sections may be utilized such as an elliptical shape, a rectangular shape, or nearly any other cross-sectional shape in which a carbon source may be provided and/or that may be used for carrying current to heat the filament.

At this point in the description, it may be useful to provide a specific example of a built and tested HWCVD apparatus to explain the desirability of a carbide filament in more detail. In this example, a TaC-coated graphite filament was positioned within a vacuum chamber between an inlet of precursor gas and a substrate mounted upon a heater. Specifically, in this implementation, the carbide filament had a length of about four inches and an outer diameter of 0.064 inches. A TaC coating (i.e., a carbide coating) with a thickness in the range of about 20 to 40 microns was provided on the graphite core of the filament (and was part of the outer diameter measurement). The carbide filament was resistively heated by passing a DC current through the filament.

The precursor was silane (SiH4), and the carbide filament was used to effectively decompose the silane for the deposition of both amorphous and epitaxial silicon thin films. A fixture was constructed to hold the filament in the CVD or vacuum chamber. The fixture was positioned so that the filament was vertically orientated at about 5 centimeters from the heated substrate. Silane gas was introduced into the vacuum chamber and metered using a flow meter. Electrical contact between the TaC-coated graphite filament and the filament holder (a stainless steel/Inconel® filament holder in this case) was made with a thin graphite foil wrapped around the ends of the filament.

The filament was heated to decompose the silane by supplying currents ranging from about 24 to 40 amperes to the filament via the foil contacts with the use of a constant current DC power supply or source. During the test, an amorphous silicon film was deposited on a crystalline silicon wafer with native oxide while the substrate was heated to about 350° C. by the heater. During another stage of the testing with this carbide filament and HWCVD apparatus, an epitaxial silicon film was successfully deposited on a bare crystalline silicon wafer at a substrate temperature of about 775° C.

Additional testing was performed with TaC-coated graphite filaments and also standard HWCVD filaments to show the improved performance of the carbide filaments. Specifically, an exemplary TaC-coated graphite filament and a tungsten filament were both exposed to silane during a HWCVD process for purposes of comparison. Characterization of the two filament materials before and after the hot wire process allows for ready determination of the improved TaC stability and durability in the reactive silane deposition environment when compared with a pure tungsten filament.

After the deposition processes, the visual appearance of the TaC-coated filament was unchanged as was its diameter (e.g., diameter not increased near ends near contacts). The TaC-coated graphite filament had a surface that retained its shiny golden color with no indication of swelling or degradation, which suggests that the filament is stable after prolonged exposure of the hot filament to a reactive silane environment (e.g., greater than one hour with greater than about 7 microns of thin film deposition). In direct contrast, visual inspection of a tungsten filament after similar silane exposure and thin film deposition processes shows spots or portions near its ends, which were proximate to electrical contacts and likely at lower temperatures during deposition, that are visibly swollen and discolored. This indicates that silicide is forming on the filament, which will cause the filament to have brittle portions and likely fail or break in the effected region.

Scanning electronic microscope (SEM) images of an exemplary TaC-coated graphite filament were taken both before and after their use in the above testing. Specifically, SEM images were obtained before and after exposure of the TaC-coated graphite filaments to reactive silane environments for over 60 minutes during thin film deposition. The virgin TaC-coated graphite filaments showed grains on outer surfaces that were tens of microns in diameter with some cracks and pinholes in the carbide coating. Similar SEM images of the post-deposition TaC-coated graphite filaments showed that the surface TaC coating are nearly identical to those of the virgin filaments, except that the surface appeared somewhat smoother and/or cleaner.

Based on this SEM-based examination, there was no evidence of silicide formation after exposure to silane (although a small area on one side of the filament had some features consistent with silicon deposition). Further, it should be noted that the graphite used for these test filaments was not optimized for thermal expansion, as likely will be useful, and the case, in commercial implementations of the carbide filaments taught with this description and supporting figures. In the tested filaments, the graphite core likely had a lower coefficient of thermal expansion (CTE) than the coating, which may have caused some opening of cracks upon cooling of the filament after deposition and/or initial formation of the coating. Hence, in fabrication of carbide filaments, it may be useful to vary the CTE of the carbon source/core (e.g., of the graphite core) used to form the carbide-coated filament to control and even minimize these thermal expansion/contraction effects.

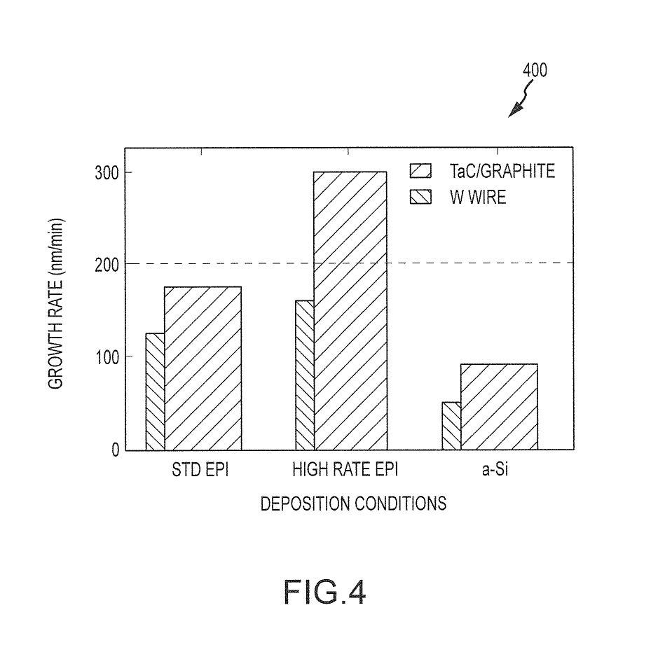

FIG. 4 provides a graph 400 plotting deposition rates achieved during testing with a carbide-coated filament (i.e., tantalum carbide coating a graphite core) and with a conventional tungsten filament. More specifically, the graph 400 is a plot comparison of deposition rates for standard epitaxial (epi) silicon (Si), high rate epi, and amorphous Si (a-Si) deposited using an exemplary TaC-coated graphite filament and a tungsten (W) filament. Comparison of the growth rates of a thin film (deposition rates) obtained with the TaC-coated graphite filament to those obtained with a conventional W filament provides a ready illustration of the efficacy of the carbide filaments described herein with new reaction-resistive filament materials.

At currents greater than 29 amps for creating the data of graph 400, the deposition or growth rates of a deposition apparatus using the TaC-coated graphite filament exceeded those obtained with a standard tungsten filament for both amorphous and epitaxial silicon. The resulting higher deposition rates for the same gas conditions were measured as growth rates of up to about 91 nm/minute and about 300 nm/minute for amorphous and epitaxial silicon, respectively, for the TaC-coated graphite filaments. These improved deposition rates were likely the result of the filaments providing increased area (none lost to silicide or the like), higher filament temperatures, and/or access to differing chemistry for deposition implementations. The TaC-coated graphite filament exceeded the highest deposition rates preciously achieved in the test deposition apparatus with a single tungsten filament by more than 100 nm/minute, which represents an improvement of over 50 percent.

As will be understood from the above discussion with reference to FIGS. 1-4, HWCVD systems/assemblies are described that include hot wires or filaments formed using a new filament material. For example, the new filament materials may include a graphite core with a coating or outer layer of tantalum carbide (i.e., a TaC-coated graphite filament), which has been demonstrated to be stable during silicon deposition from silane precursor gas over a large temperature range. The TaC-coated graphite filament may be used for the efficient decomposition of silane to grow amorphous and epitaxial thin films in a HWCVD apparatus. Of course, it is noted that the filament may also be used to deposit other types of films with silicon being only one useful example and/or may be used with other types of deposition techniques.

The embodiments described herein also address silicidation/stability issued experienced with other filaments, and, therefore, described filaments may provide increased lifespan when used in HWCVD assemblies. The carbide filaments also exhibit stable operation over a wide range of filament temperatures as compared with prior tantalum and tungsten filaments. These features combine to enable continuous processing without the downtime associated with frequent filament changes. The increased lifespan and stable operation over a wide range of temperatures may have particular applicability to large scale (e.g., commercial) HWCVD implementations with the carbide filaments.

It will be readily appreciated by those skilled in the art that the carbide filaments may be used in a wide variety of applications now known or later developed. For purposes of illustration, exemplary embodiments described herein may be used in the HWCVD of materials such as silicon thin films and epitaxial layers from silane. The TaC-coated graphite filament may be used in thin film deposition processes, but it will be understood that many other carbides may be utilized to fabricate the carbide filaments (e.g., filament 120 of FIG. 1 is not limited to a TaC filament). The carbide filament may include any number of metallic or semi-metallic carbides alone or in combination. For example, tungsten carbide may be utilized for providing a coating layer over a graphite core. Hence, the term “carbide” is intended to be construed relatively broadly as long as the resulting filament is properly electrically conductive to provide a high temperature (e.g., over about 1000° C. and, more typically, over 1400° C.) resistive heating element, is structurally sound (e.g., can be used to manufacture filaments of useful shapes that will not readily fail during repeated use), and is durable in the high temperature, reactive environment found in most deposition chambers (e.g., the carbide coating is useful as it is less reactive than tungsten or pure tantalum as well as being more useful than pure graphite, which is considered an undesirably dirty material to include in a deposition chamber).

The described carbide filaments also may be used with a multitude of precursors and is not limited to use with silane. For example, other silicon-based precursor gases may be used such as SiCl₄, SiF₄, HSiCl₃, and the like or non-silicon precursors such as methane, GeH₄, and other precursor gases useful in material deposition such as HWCVD. Since the carbide filaments are used to crack feedstock gas to sustain a reaction, the filaments may be used for a wide variety of deposition processes and material compositions and geometries. For example, the deposition apparatus 100, 200 of FIGS. 1 and 2 may be used in the growth of oxides, carbon-based materials (such as diamond films), nanotubes, fluorocarbon materials, polymers, and the like and for use in i-CVD (initiated CVD) processes that use hot filaments to access specific gas phase chemistries for the production of biologically relevant materials and barrier coatings. In general, carbide-coated graphite filaments can be employed for use in high temperature reactive environments to effect improvements in chemical reactions and chemical dissociations.

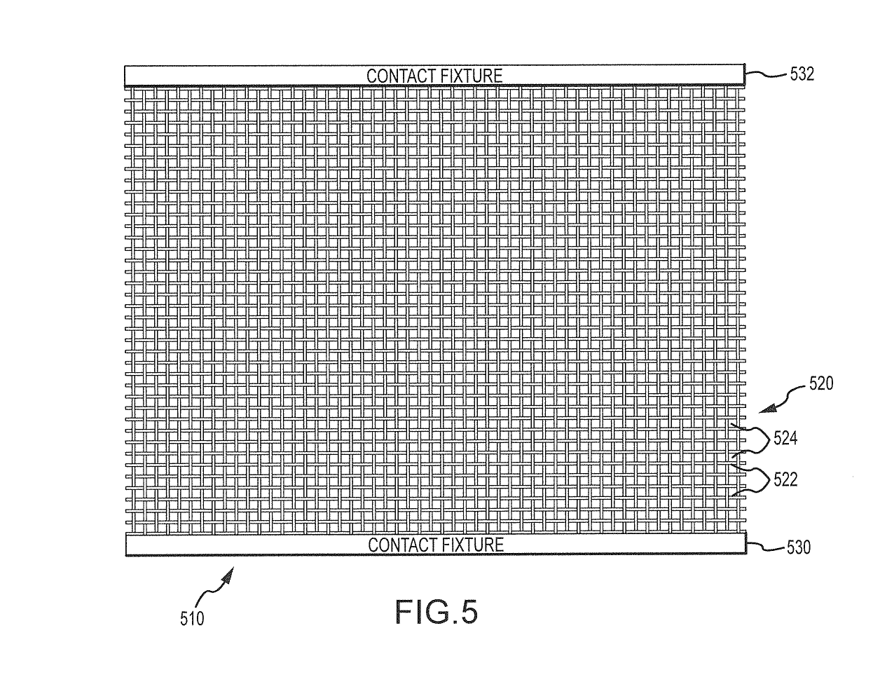

As discussed above, the “filament” is not limited to a simple rod with a circular cross section or a plurality of such rods, although such an implementation in a HWCVD apparatus often will be useful. Particularly, it may be desirable to provide a carbide filament with larger surface area between the precursor gas inlet and the heated wafer/substrate in the vacuum chamber of a deposition apparatus. To this end, FIG. 5 illustrates a filament assembly 510 that provides enhanced surface area. The filament assembly (or simply “filament”) 510 includes a pair of electrical contact fixtures 530, 532 that are attached at ends or edges of a carbide mesh or woven cloth 520.

The carbide mesh 520 may include first and second sets of wires or threads (or elongate members) 522 that extend transverse to each other between the fixtures 530, 532. As shown, the first and second wires 522 are orthogonal to each other (but this is not required) and may be thought of as being woven threads providing a “cloth” 520. The interwoven elements/wires 522 define openings or pores 524 through which a precursor gas or its decomposed radicals may flow to reach surfaces of a heated wafer or substrate during deposition processes.

The fineness of the weave or size of the pores 524 may vary widely to practice the filament 510. In some cases, the wires/threads 522 have outer diameters of less than about 40 microns and the openings/pores 524 may have similar dimensions. In other cases, the threads 522 have outer diameters of less than about 20 microns, and cloths 520 formed with such small threads may be desirable in implementations where the threads are formed solely or nearly solely of carbide rather than a graphite or other carbon source core coated with a carbide.

For example, the cloth 520 may be formed by processing a graphite cloth with threads/wires having outer diameters of 10 to 20 microns or less, and the processing may result in the cross section taking the form shown in FIG. 3B of substantially one material (e.g., TaC). The processing of the graphite cloth 520 converts at least the outer surface of the woven strands 522 of the graphite cloth 520 to TaC. This may be useful in applications where it is desired to eliminate the release of any (or nearly eliminating such release) of carbon into the deposition chamber. The assembly 510 provides a large surface area filament with cloth 520 that can be suspended between two electrical connectors 530, 532. In use, the filament assembly 510 likely will provide higher process gas decomposition and higher deposition rates for thin films being grown on a wafer/substrate. The assembly 510 also may provide cost savings as the TaC (as an exemplary carbide) is seemingly inert to many of the process gases used in HWCVD. The cloth 520 may also be more flexible and less likely to break than a solid TaC-coated graphite filament (unless stress relieving portions are provided such as a coiled or spring section that accounts for expansion and contraction utilizing the physical characteristics of a graphite core).

It may be useful at this point in the description to describe methods and results of a further test performed on a TaC-coated graphite filament in a HWCVD apparatus. A purpose of the test was to determine current and power characteristics of the new TaC filament and also measure deposition rates for amorphous and epitaxial silicon on silicon wafers. The TaC-coated graphite filament was used with the intent to achieve high deposition rates for c-Si using the more stable TaC-coated filament (rather than a pure tantalum or tungsten filament).

The test method involved installing a filament (graphite core coated with layer of TaC) into a filament holder using graphite foil for electrical contacts. The filament tested was 4 inches long and had an outer diameter of 1.63 mm, and it was positioned between an inlet for a precursor or feedstock gas (i.e., silane) and a heater heating the silicon wafer within the vacuum chamber. Silane was caused to flow under standard conditions (20 sccm, 10 mTorr) and the deposition rate for a-Si:H (initial substrate temperature of about 200° C.) and epitaxial silicon (initial substrate temperature of about 660° C.).

Initially, with no gas flowing, currents of 1 to 31 amps were introduced into the filament, and voltage, power, and resistance were measured, which indicated acceptable electrical conductivity for a resistive heating element (e.g., a catalytic decomposition element). Higher currents were then applied to the filament (24 to 40 amps) and precursor gas was injected into the chamber. Amorphous silicon was deposited at rates between 16 and about 91 nm/minute, which is a deposition rate of nearly double the rate achieved for a standard (0.02-inch outer diameter) tungsten filament. Epitaxial silicon was deposited in a separate testing (with a differing wafer) at rates between about 145 and 294 nm/minute, and this deposition rate in prior experiments would have required two tungsten filaments and was as high as previously measured with the test equipment. This higher deposition rate is believed to be due, at least partially, to an increased filament temperature that increases cracking of the silane (e.g., in the test, up to about 400 W was put into the TaC-coated graphite filament).

While a number of exemplary aspects and embodiments have been discussed above, those of skill in the art will recognize certain modifications, permutations, additions, and sub-combinations thereof. It is therefore intended that the following appended claims and claims hereafter introduced are interpreted to include modifications, permutations, additions, and sub-combinations to the exemplary aspects and embodiments discussed above as are within their true spirit and scope.

1. A hot wire chemical vapor deposition (HWCVD) apparatus, comprising:
a deposition chamber operable at vacuum;
a source of precursor gas including a gas inlet for injecting a volume of the precursor gas into the deposition chamber;
a heater with a support surface exposed to the deposition chamber, the heater operable to heat a substrate positioned upon the support surface; and
a catalytic decomposition assembly comprising a filament positioned between the support surface of the heater and the precursor gas inlet and further comprising a power source for selectively passing a current through the filament to resistively heat material of the filament, wherein the filament material comprises a carbide.

2. The apparatus of claim 1, wherein the carbide comprises tantalum carbide.

3. The apparatus of claim 2, wherein the tantalum carbide is provided as an outer layer that coats a carbon source core.

4. The apparatus of claim 3, wherein the carbon source core comprises graphite.

5. The apparatus of claim 1, wherein the filament is heated to a temperature of at least about 2000° C. during operation of the power source.

6. The apparatus of claim 1, wherein the precursor gas comprises silane, SiCl₄, SiF₄, HSiCl₃, methane, or GeH₄ and the carbide is a coating over a graphite core, the carbide coating comprising an alloy of carbon and a metallic or semi-metallic element.

7. The apparatus of claim 1, wherein the carbide comprises an alloy of carbon and at least one of tantalum, tungsten, molybdenum, niobium, scandium, yttrium, zirconium, silicon, and vanadium.

8. A deposition assembly for use in fabricating a device with a thin film of material by cracking a source gas, comprising:
a vacuum chamber configured to receive the source gas;
a mounting surface within the vacuum chamber for supporting a wafer; and
a filament assembly comprising a filament with an outer surface formed of carbide and electrical contacts for applying a current to the filament, wherein the filament is heated to a temperature of at least 1400° C. when the current is applied.

9. The assembly of claim 8, wherein the filament comprises a sheet of interwoven filament elements each comprising at least a carbide coating with a plurality of pores among the filament elements through which the source gas flows to contact a wafer on the mounting surface.

10. The assembly of claim 8, wherein the carbide outer surface comprises a thickness of an alloy of carbon and at least one of tantalum, tungsten, molybdenum, niobium, scandium, yttrium, zirconium, silicon, and vanadium.

11. The assembly of claim 10, wherein the carbide outer surface comprises tantalum carbide and has a thickness of at least about 10 microns.

12. The assembly of claim 8, wherein the filament comprises a core formed of graphite.

13. The assembly of claim 12, wherein the filament comprises at least one stress relief section configured structurally to expand and contract with temperature changes.

14. The assembly of claim 8, wherein the mounting surface is a portion of a heater and is heated to a temperature of at least 500° C. and wherein the filament is heated to a temperature of at least 2000° C. by the current.

15. The assembly of claim 14, the substrate comprises silicon, wherein the source gas comprises silane, and wherein the carbide comprises tantalum carbide.

16. A thin film deposition method, comprising:
positioning a resistive heater filament within a deposition chamber, the resistive heater filament comprising a carbide material;
mounting a substrate on a surface of a heater facing into the deposition chamber;
with the heater, heating the substrate to an initial deposition temperature;
passing electric current through the resistive heater filament to heat the carbide material to a cracking temperature; and
flowing a deposition source gas into the chamber to flow over the resistive heater filament.

17. The method claim 16, wherein the resistive heater filament further includes a graphite core and the carbide material is provided as an outer coating covering the graphite core.

18. The method of claim 17, wherein the carbide material is an alloy of carbon and at least one of tantalum, tungsten, molybdenum, niobium, scandium, yttrium, zirconium, silicon, and vanadium.

19. The method of claim 16, wherein the cracking temperature is greater than about 2000° C. and the initial deposition temperature is greater than about 500° C.

20. The method of claim 19, wherein the deposition source gas is silane, wherein the substrate comprises silicon, and wherein the carbide material comprises tantalum or tungsten carbide.
